(19) United States
(12) Patent Application Publication
(10) Pub. No.: US 2021/0078035 A1
(43) Pub. Date: Mar. 18, 2021

(54) COATING METHOD, COATING APPARATUS, AND STORAGE MEDIUM

(71) Applicant: Tokyo Electron Limited, Tokyo (JP)

(72) Inventors: Yusaku HASHIMOTO, Kumamoto (JP); Masatoshi KAWAKITA, Kumamoto (JP); Daiki SHIBATA, Kumamoto (JP)

(21) Appl. No.: 17/017,799

(22) Filed: Sep. 11, 2020

(30) Foreign Application Priority Data
Sep. 13, 2019 (JP) 2019-167457

(51) Int. Cl. B05D 1/00; B05C 9/14; B05C 5/00; G03F 7/16; H01L 21/027

(52) U.S. Cl. CPC B05D 1/002; B05C 9/14; H01L 21/0273; G03F 7/162; B05C 5/001

(57) ABSTRACT

A coating method, includes: rotating a substrate at a first rotation speed while supplying a film-forming liquid to a center of a front surface of the substrate; stopping the supply of the film-forming liquid before the film-forming liquid supplied to the front surface of the substrate reaches an outer periphery of the substrate; continuing to rotate the substrate at a second rotation speed after the supply of the film-forming liquid is stopped; and supplying a cooling fluid, which is a gas-liquid mixture, to an outer peripheral portion of a rear surface of the substrate during a supply period for the substrate including at least a part of a period from a time when the supply of the film-forming liquid is stopped to a time when the rotation of the substrate at the second rotation speed is completed.

### CROSS-REFERENCE TO RELATED APPLICATION

This application is based upon and claims the benefit of priority from Japanese Patent Application No. 2019-167457, filed on Sep. 13, 2019, the entire contents of which are incorporated herein by reference.

### TECHNICAL FIELD

The present disclosure relates to a coating method, a coating apparatus, and a storage medium.

### BACKGROUND

In Patent Document 1, there is disclosed a coating apparatus that includes a substrate holder configured to hold a substrate, a rotator configured to rotate the substrate held by the substrate holder, a supplier configured to supply a coating liquid to the surface of the substrate held by the substrate holder, and an air flow control plate provided at a predetermined position above the substrate held by the substrate holder and configured to locally change an air flow above the substrate rotated by the rotator at an arbitrary position.

### PRIOR ART DOCUMENT

[Patent Document]

### (Patent Document 1) Japanese Patent Application Publication No. 2012-238838

### SUMMARY

According to one embodiment of the present disclosure, a coating method includes: rotating a substrate at a first rotation speed while supplying a film-forming liquid to a center of a front surface of the substrate; stopping the supply of the film-forming liquid before the film-forming liquid supplied to the front surface of the substrate reaches an outer periphery of the substrate; continuing to rotate the substrate at a second rotation speed after the supply of the film-forming liquid is stopped; and supplying a cooling fluid, which is a gas-liquid mixture, to an outer peripheral portion of a rear surface of the substrate during a supply period for the substrate including at least a part of a period from a time when the supply of the film-forming liquid is stopped to a time when the rotation of the substrate at the second rotation speed is completed.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram illustrating a schematic configuration of a substrate liquid processing system.

FIG. 2 is a schematic diagram illustrating a schematic configuration of a coating unit.

FIG. 3 is a block diagram illustrating a functional configuration of a controller.

FIG. 4 is a block diagram illustrating a hardware configuration of the controller.

FIG. 5 is a flowchart illustrating a coating procedure.

FIG. 6 is a flowchart illustrating the coating procedure.

FIG. 7 is a flowchart illustrating the coating procedure.

FIGS. 8A, 8B and 8C are schematic diagrams showing the states of a wafer when coating a pre-wetting liquid.

FIGS. 9A, 9B and 9C are schematic diagrams showing the states of the wafer during the supply of a resist liquid.

FIGS. 10A, 10B and 10C are schematic diagrams showing the states of the wafer when stopping the supply of the resist liquid and spreading the resist liquid.

FIG. 11 is a flowchart illustrating a procedure for setting coating conditions.

FIG. 12 is a flowchart illustrating a procedure for automatically adjusting a first coating speed and a supply period.

FIG. 13 is a flowchart illustrating a procedure for optimizing the first coating speed.

FIG. 14 is a flowchart illustrating the procedure for optimizing the first coating speed.

FIG. 15 is a flowchart illustrating a modification of the procedure for automatically adjusting the first coating speed and the supply period.

FIG. 16 is a flowchart illustrating a procedure for temporarily determining the first coating speed.

FIG. 17 is a flowchart illustrating a modification of the procedure for automatically adjusting the first coating speed and the supply period.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In the description, the same elements or elements having the same function will be denoted by like reference numerals, and the redundant description thereof will be omitted.

### [Substrate Processing System]

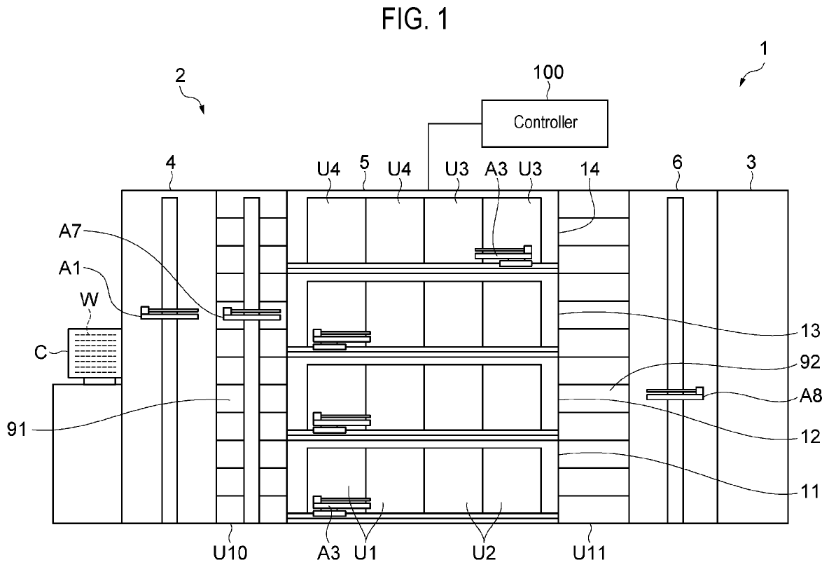

As shown in FIG. 1, the substrate processing system 1 is a system for forming a photosensitive film on a substrate, exposing the photosensitive film, and developing the photosensitive film. The target substrate is, for example, a semiconductor wafer W. The photosensitive film is, for example, a resist film. The substrate processing system 1 includes a coating/developing apparatus 2 and an exposure apparatus 3. The exposure apparatus 3 performs an exposure process on a resist film (photosensitive film) formed on a wafer W (substrate). Specifically, an energy ray is irradiated on the exposure target portion of the resist film by a method such as immersion exposure or the like. The coating/developing apparatus 2 performs a process of forming a resist film on the surface of the wafer W (substrate) before the exposure process performed by the exposure apparatus 3, and performs a process of developing the resist film after the exposure process.

### [Coating Apparatus]

The configuration of the coating/developing apparatus 2 will be described below as an example of the coating apparatus. The coating/developing apparatus 2 includes a carrier block 4, a processing block 5, an interface block 6, and a controller 100.

The carrier block 4 loads the wafer W into the coating/developing apparatus 2 and unloads the wafer W from the coating/developing apparatus 2. For example, the carrier block 4 can support a plurality of carriers C for wafers W and is equipped with a delivery arm A1. The carrier C accommodates, for example, a plurality of circular wafers W. The delivery arm A1 takes out the wafer W from the carrier C, transfers the wafer W to the processing block 5, receives the wafer W from the processing block 5, and returns the wafer W into the carrier C.

The processing block 5 has a plurality of processing modules 11, 12, 13 and 14. Each of the processing modules 11, 12 and 13 includes a coating unit U1, a heat treatment unit U2, and a transfer arm A3 that transfers the wafer W to the coating unit U1 and the heat treatment unit U2.

The processing module 11 forms a lower layer film on the surface of the wafer W by the coating unit U1 and the heat treatment unit U2. The coating unit U1 of the processing module 11 coats a film-forming liquid for forming the lower layer film on the wafer W. The heat treatment unit U2 of the processing module 11 performs various heat treatments associated with the formation of the lower layer film.

The processing module 12 forms a resist film on the lower layer film by the coating unit U1 and the heat treatment unit U2. The coating unit U1 of the processing module 12 coats a film-forming liquid for forming a resist film (hereinafter referred to as “resist liquid”) on the lower layer film. The heat treatment unit U2 of the processing module 12 performs various heat treatments associated with the formation of the resist film.

The processing module 12 may further include a substrate cooler 91 and a surface inspector 92. The substrate cooler 91 cools the wafer W before the coating unit U1 coats the resist liquid on the wafer W. The surface inspector 92 acquires information about the film thickness of the resist film formed on a front surface Wa of the wafer W (hereinafter referred to as “film thickness information”). For example, the surface inspector 92 acquires a pixel value in a captured image of the front surface Wa of the wafer W as an example of the film thickness information. The pixel value is a numerical value indicating the state of each pixel forming the image. For example, the pixel value is a numerical value indicating the shade level of a color of a pixel (for example, the gray level in a monochrome image). In the captured image of the front surface Wa, the pixel value correlates with the height of the imaging target portion corresponding to the pixel. That is, the pixel value also correlates with the thickness of the resist film in the imaging target portion.

The processing module 13 forms an upper layer film on the resist film by the coating unit U1 and the heat treatment unit U2. The coating unit U1 of the processing module 13 coats a film-forming liquid for forming the upper layer film on the resist film. The heat treatment unit U2 of the processing module 13 performs various heat treatments associated with the formation of the upper layer film.

The processing module 14 includes a developing unit U3, a heat treatment unit U4, and a transfer arm A3 that transfers the wafer W to the developing unit U3 and the heat treatment unit U4. The processing module 14 develops the resist film after exposure by the developing unit U3 and the heat treatment unit U4. The developing unit U3 coats a developing liquid onto the surface of the exposed wafer W and then rinses the developing liquid off with a rinse liquid, thereby developing the resist film. The heat treatment unit U4 performs various heat treatments associated with the development process. Specific examples of the heat treatment include a heat treatment before the development process (PEB: Post Exposure Bake), a heat treatment after the development process (PB: Post Bake), and the like.

A shelf unit U10 is installed on the side of the carrier block 4 (near the carrier block 4) in the processing block 5. The shelf unit U10 is divided into a plurality of cells arranged in the vertical direction. An elevating arm A7 is installed near the shelf unit U10. The elevating arm A7 raises and lowers the wafer W between the cells of the shelf unit U10.

A shelf unit U11 is installed on the side of the interface block 6 (near the interface block 6) in the processing block 5. The shelf unit U11 is divided into a plurality of cells arranged in the vertical direction.

The interface block 6 delivers the wafer W to and from the exposure apparatus 3. For example, the interface block 6 includes a built-in delivery arm A8 and is connected to the exposure apparatus 3. The delivery arm A8 delivers the wafer W arranged on the shelf unit U11 to the exposure apparatus 3, receives the wafer W from the exposure apparatus 3, and returns the wafer W to the shelf unit U11.

The controller 100 controls the coating/developing apparatus 2 so as to execute a coating/developing process, for example, in the following procedure. First, the controller 100 controls the delivery arm A1 so as to transfer the wafer W in the carrier C to the shelf unit U10, and controls the elevating arm A7 so as to arrange the wafer W in a cell for the processing module 11.

Next, the controller 100 controls the transfer arm A3 to transfer the wafer W of the shelf unit U10 to the coating unit U1 and the heat treatment unit U2 in the processing module 11, and controls the coating unit U1 and the heat treatment unit U2 so as to form a lower layer film on the surface of the wafer W. Thereafter, the controller 100 controls the transfer arm A3 so as to return the wafer W on which the lower layer film is formed to the shelf unit U10, and controls the elevating arm A7 so as to arrange the wafer W in a cell for the processing module 12.

Next, the controller 100 controls the transfer arm A3 so as to transfer the wafer W of the shelf unit U10 to the coating unit U1 and the heat treatment unit U2 in the processing module 12, and controls the coating unit U1 and the heat treatment unit U2 so as to form a resist film on the lower layer film of the wafer W. Thereafter, the controller 100 controls the transfer arm A3 so as to return the wafer W to the shelf unit U10, and controls the elevating arm A7 so as to arrange the wafer W in a cell for the processing module 13.

Next, the controller 100 controls the transfer arm A3 so as to transfer the wafer W of the shelf unit U10 to each unit in the processing module 13, and controls the coating unit U1 and the heat treatment unit U2 so as to form an upper layer film on the resist film of the wafer W. Thereafter, the controller 100 controls the transfer arm A3 so as to transfer the wafer W to the shelf unit U11.

Next, the controller 100 controls the delivery arm A8 so as to send the wafer W of the shelf unit U11 to the exposure apparatus. Thereafter, the controller 100 controls the delivery arm A8 so as to receive the wafer W subjected to the exposure process from the exposure apparatus and arrange the wafer W in a cell of the shelf unit U11 for the processing module 14.

Next, the controller 100 controls the transfer arm A3 so as to transfer the wafer W of the shelf unit U11 to each unit in the processing module 14, and controls the developing unit U3 and the heat treatment unit U4 so as to perform a developing process on the resist film of the wafer W. Thereafter, the controller 100 controls the transfer arm A3 so as to return the wafer W to the shelf unit U10, and controls the elevating arm A7 and the delivery arm A1 so as to return the wafer W into the carrier C. Thus, the coating/developing process is completed.

The specific configuration of the substrate processing apparatus is not limited to the configuration of the coating/developing apparatus 2 illustrated above. The substrate processing apparatus may be any apparatus as long as it includes the coating unit U1 and the controller 100 capable of controlling the coating unit U1.

### [Coating Unit]

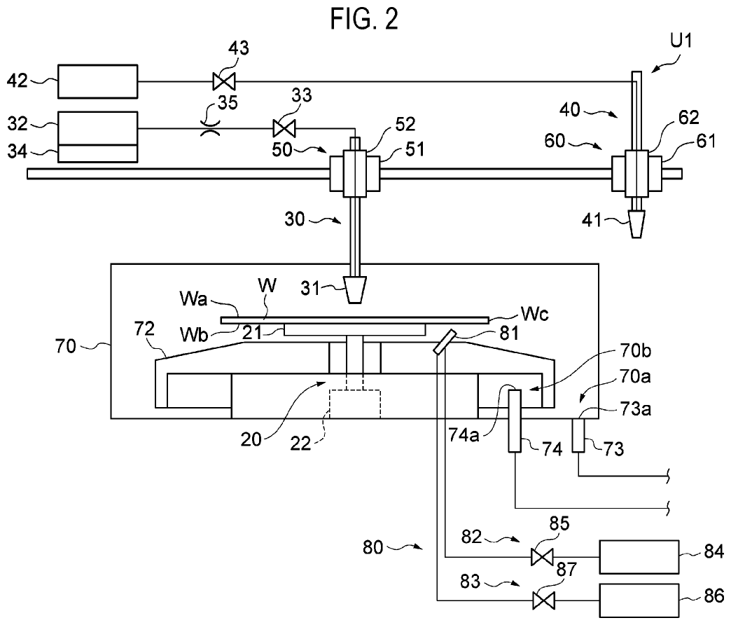

Next, the configuration of the coating unit U1 of the processing module 12 will be specifically described. As shown in FIG. 2, the coating unit U1 includes a rotary holder 20, liquid suppliers 30 and 40, nozzle transporters 50 and 60, a cup 70, and a cooling fluid supplier 80.

The rotary holder 20 rotates the wafer W while holding and supporting a rear surface Wb of the wafer W. For example, the rotary holder 20 includes a holder 21 and a rotational driver 22. The holder 21 supports the rear surface Wb of the central portion (the portion including the center) of the wafer W horizontally arranged with the front surface Wa facing upward, and holds the wafer W by, for example, vacuum suction. The rotational driver 22 rotates the holder 21 about a vertical axis passing through the center of the wafer W by using, for example, an electric motor or the like as a power source. As a result, the wafer W is also rotated.

The liquid supplier 30 supplies a resist liquid to the center of the front surface Wa of the wafer W held by the rotary holder 20. For example, the liquid supplier 30 supplies a resist liquid having a viscosity of 5 cP or less to the front surface Wa of the wafer W. For example, the liquid supplier 30 includes a nozzle 31, a liquid source 32, and a valve 33.

The nozzle 31 discharges a resist liquid downward. The liquid source 32 (film-forming liquid supply source) supplies the resist liquid to the nozzle 31. For example, the liquid source 32 includes a tank that stores the resist liquid, a pump that pressure-feeds the resist liquid, and the like. The liquid source 32 may be configured to be able to adjust the liquid feeding pressure of the resist liquid by a pump or the like. The valve 33 opens and closes the flow path of the resist liquid extending from the liquid source 32 to the nozzle 31.

The liquid supplier 30 may further include a liquid cooler 34 and a throttle portion 35. The liquid cooler 34 cools the resist liquid supplied from the liquid source 32 to the nozzle 31. For example, the liquid cooler 34 cools the resist liquid stored in the tank of the liquid source 32. Specific examples of the liquid cooler 34 include an air cooling type cooling device, a water cooling type cooling device, and a heat pump type cooling device.

The throttle portion 35 is installed between the liquid source 32 and the valve 33 in the liquid feeding pipe for the resist liquid extending from the liquid source 32 to the nozzle 31. When the liquid supplier 30 includes the throttle portion 35, the act of supplying the film-forming liquid to the center of the front surface Wa of the wafer W by the liquid supplier 30 includes the act of supplying the film-forming liquid from the liquid source 32 through the nozzle 31, the throttle portion 35, and the valve 33.

The throttle portion 35 narrows the flow path of the resist liquid to reduce the change in the supply amount (supply amount per unit time) of the resist liquid caused by the change in the liquid feeding pressure. Hereinafter, the magnitude of the change in the supply amount caused by the change in the liquid feeding pressure is referred to as “supply amount adjustment resolution.” The throttle portion 35 may be configured such that the supply amount adjustment resolution in the case of providing the throttle portion 35 is ½ or less, ⅓ or less, or ¼ or less of the supply amount adjustment resolution in the case of not providing the throttle portion 35.

For example, the throttle portion 35 includes a flow path having an inner diameter smaller than that of the liquid feeding pipe. The ratio of the inner diameter of the flow path of the throttle portion 35 to the inner diameter of the liquid feeding pipe is, for example, 5.0 to 25.0%, preferably 6.0 to 20.0%, and more preferably 7.5 to 18.0%. A specific example of the throttle portion 35 is an orifice type throttle valve. However, the present disclosure is not limited thereto. The throttle portion 35 may have any shape and structure as long as it can reduce the supply amount adjustment resolution.

The liquid supplier 40 supplies a pre-wetting liquid to the front surface Wa of the wafer W held by the holder 21. For example, the liquid supplier 40 supplies an organic solvent such as thinner or the like to the front surface Wa of the wafer W. For example, the liquid supplier 40 includes a nozzle 41, a liquid source 42, and a valve 43.

The nozzle 41 discharges the pre-wetting liquid downward. The liquid source 42 supplies the pre-wetting liquid to the nozzle 41. For example, the liquid source 42 includes a tank that stores the pre-wetting liquid, a pump that pressure-feeds the pre-wetting liquid, and the like. The valve 43 opens and closes the flow path of the pre-wetting liquid extending from the liquid source 42 to the nozzle 41. The valve 43 may be configured to be able to adjust the opening degree of the flow path of the pre-wetting liquid. This makes it possible to adjust the discharge amount of the pre-wetting liquid discharged from the nozzle 41.

The nozzle transporter 50 transports the nozzle 31 of the liquid supplier 30. For example, the nozzle transporter 50 includes a horizontal transporter 51 and an elevator 52. The horizontal transporter 51 transports the nozzle 31 along a horizontal transport line using, for example, an electric motor as a power source. The elevator 52 raises and lowers the nozzle 31 using, for example, an electric motor as a power source.

The nozzle transporter 60 transports the nozzle 41 of the liquid supplier 40. For example, the nozzle transporter 60 includes a horizontal transporter 61 and an elevator 62. The horizontal transporter 61 transports the nozzle 41 along a horizontal transport line using, for example, an electric motor as a power source. The elevator 62 raises and lowers the nozzle 41 by using, for example, an electric motor as a power source.

The cup 70 accommodates the wafer W together with the holder 21, and collects various processing liquids (e.g., the resist liquid and the pre-wetting liquid) shaken off from the wafer W. The cup 70 includes an umbrella portion 72, a liquid drainage portion 73, and an exhaust portion 74. The umbrella portion 72 is installed below the holder 21, and guides various processing liquids shaken off from the wafer W to a liquid drainage region 70a on the outer peripheral side in the cup 70. The liquid drainage portion 73 has a liquid drainage port 73a opened toward the inside of the cup 70 (toward the accommodation space for the wafer W) below the umbrella portion 72 (i.e., below the rear surface Wb of the wafer W). The liquid drainage portion 73 drains the processing liquid from the liquid drainage port 73a to the outside of the cup 70. For example, the liquid drainage port 73a is installed below the umbrella portion 72 in the liquid drainage region 70a. Therefore, the processing liquid guided to the liquid drainage region 70a by the umbrella portion 72 is drained from the liquid drainage port 73a to the outside of the cup 70.

The exhaust portion 74 has an exhaust port 74a opened toward the inside of the cup 70 below the holder 21 (i.e., below the rear surface Wb of the wafer W). The exhaust portion 74 discharges the gas in the cup 70 (the gas in the accommodation space of the wafer W) from the exhaust port 74a to the outside of the cup 70. For example, the exhaust port 74a is installed below the umbrella portion 72 in an exhaust region 70b inside the liquid drainage region 70a. Therefore, the gas flowing from the liquid drainage region 70a into the exhaust region 70b is discharged from the exhaust port 74a to the outside of the cup 70.

The cooling fluid supplier 80 supplies a cooling fluid as a gas-liquid mixture to the outer peripheral portion of the rear surface Wb of the wafer W. As a result, the annular region of the rear surface Wb extending along an outer periphery We of the wafer W is cooled. For example, the cooling fluid supplier 80 supplies a cooling fluid containing a mist-like cooling liquid to the outer peripheral portion of the rear surface Wb of the wafer W. For example, the cooling fluid supplier 80 includes a spray nozzle 81, a cooling liquid supplier 82, and a cooling gas supplier 83.

The spray nozzle 81 discharges a mist of the cooling liquid by spraying the cooling gas on the cooling liquid. Since the spray nozzle 81 supplies the cooling liquid as a mist, the cooling liquid is likely to remain on the outer peripheral portion of the rear surface Wb of the wafer W until it is volatilized. Therefore, it is possible to more efficiently cool the outer peripheral portion of the rear surface Wb of the wafer W.

The spray nozzle 81 is disposed below the rear surface Wb of the wafer W so as to supply the cooling fluid to the outer peripheral portion of the rear surface Wb of the wafer W along an inclined line which is inclined so as to come close to the outer periphery Wc of the wafer W as it approaches the rear surface Wb of the wafer W. For example, a vector in the supply direction of the cooling fluid along the line may be inclined toward the outer periphery Wc so as to form an angle of 0 to 90° with respect to a vector directed vertically upward. The line may be further inclined toward the movement direction of the outer periphery Wc of the wafer W as it approaches the rear surface Wb of the wafer W. For example, the line may be inclined in the same direction as the direction of rotation of the wafer W such that, when viewed from vertically above, a vector in the supply direction of the cooling fluid along the line makes an angle of 0 to 90° with respect to a vector going outward from the center of the wafer W. Due to these inclinations, the location where the cooling fluid adheres can be concentrated on the outer peripheral portion of the wafer W. As a result, it is possible to suppress unexpected cooling of the central portion of the wafer W.

The cooling liquid supplier 82 supplies the cooling liquid to the spray nozzle 81. The cooling liquid is a solvent having volatility equal to or higher than volatility of isopropyl alcohol (IPA), for example, a volatile solvent such as isopropyl alcohol (IPA), thinner or acetone. In particular, according to IPA, the outer peripheral portion of the rear surface Wb of the wafer W can be cooled more efficiently due to its high volatility. For example, the cooling liquid supplier 82 includes a liquid source 84 and a valve 85. The liquid source 84 includes a tank that stores the cooling liquid, a pump that pressure-feeds the cooling liquid, and the like. The valve 85 opens and closes the flow path of the cooling liquid extending from the liquid source 84 to the spray nozzle 81. The valve 85 may be configured to adjust the opening degree of the flow path of the cooling liquid. This makes it possible to adjust the supply amount of the cooling liquid to the spray nozzle 81.

The cooling gas supplier 83 supplies the cooling gas to the spray nozzle 81. The cooling gas is an inert gas such as nitrogen gas or the like. For example, the cooling gas supplier 83 includes a gas source 86 and a valve 87. The gas source 86 includes a tank or the like that stores a compressed cooling gas. The valve 87 opens and closes the flow path of the cooling gas extending from the gas source 86 to the spray nozzle 81. The valve 87 may be configured to be able to adjust the opening degree of the flow path of the cooling gas. This makes it possible to adjust the supply amount of the cooling gas to the spray nozzle 81.

The coating unit U1 thus configured is controlled by the controller 100. The controller 100 is configured to execute coating control that includes: rotating the wafer W by the rotary holder 20 at a first rotation speed while supplying the resist liquid to the center of the front surface Wa of the wafer W by the liquid supplier 30; stopping the supply of the resist liquid by the liquid supplier 30 before the resist liquid supplied to the front surface Wa reaches the outer periphery We of the wafer W; continuing to rotate the wafer W by the rotary holder 20 at a second rotation speed after the supply of the resist liquid by the liquid supplier 30 is stopped; and supplying the cooling fluid to the outer peripheral portion of the rear surface Wb by the cooling fluid supplier 80 during a supply period including at least a part of a period from the time when the supply of the resist liquid by the liquid supplier 30 is stopped to the time when the rotation of the wafer W at the second rotation speed is completed.

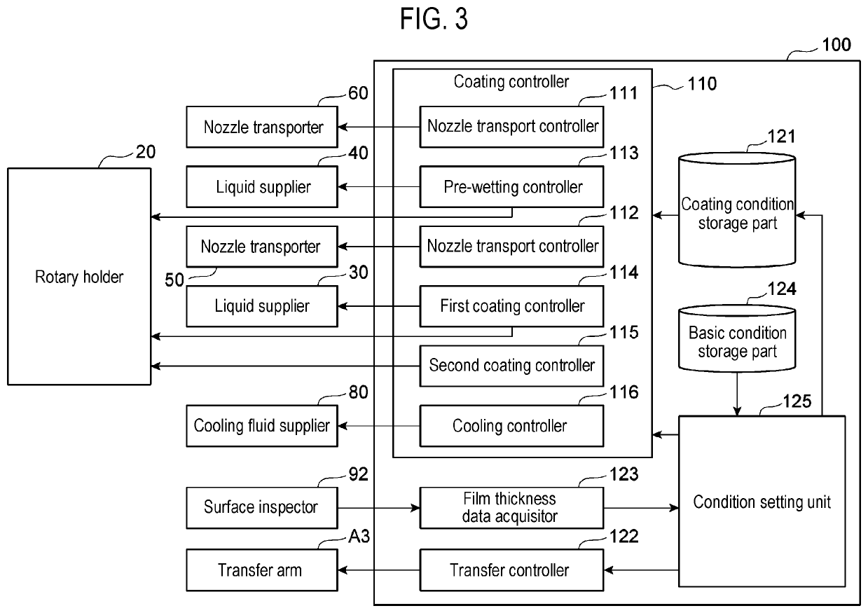

As illustrated in FIG. 3, the controller 100 includes a coating controller 110, a coating condition storage 121, and a transfer controller 122, as functional configurations (hereinafter referred to as “functional modules”). The coating controller 110 performs the aforementioned coating control. For example, the coating controller 110 includes a pre-wetting controller 113, a first coating controller 114, nozzle transport controllers 111 and 112, a second coating controller 115, and a cooling controller 116, as subdivided functional modules.

The pre-wetting controller 113 controls the liquid supplier 40 and the rotary holder 20 so as to apply the pre-wetting liquid to the front surface Wa of the wafer W. For example, the pre-wetting controller 113 causes the liquid supplier 40 to supply the pre-wetting liquid to the center of the front surface Wa of the wafer W while rotating the wafer W at a predetermined rotation speed (hereinafter referred to as “first pre-wetting speed”) by the rotary holder 20, and causes the liquid supplier 40 to stop the supply of the pre-wetting liquid after supplying a predetermined amount of the pre-wetting liquid.

Thereafter, the pre-wetting controller 113 rotates the wafer W at a predetermined rotation speed (hereinafter referred to as “second pre-wetting speed”) higher than the first pre-wetting speed, thereby spreading the pre-wetting liquid toward the outer periphery Wc of the wafer W. The pre-wetting controller 113 causes the rotary holder 20 to continuously rotate the wafer W at the second pre-wetting speed until the excess pre-wetting liquid is shaken off from the front surface Wa. The first pre-wetting speed is, for example, 0 to 100 rpm. The second pre-wetting speed is, for example, 1000 to 3000 rpm.

The first coating controller 114 controls the liquid supplier 30 and the rotary holder 20 so as to coat the resist liquid on a region of the front surface Wa of the wafer W inside the outer periphery Wc. The first coating controller 114 causes the rotary holder 20 to rotate the wafer W at the first rotation speed (hereinafter referred to as “first coating speed”) while supplying the resist liquid to the center of the front surface Wa by the liquid supplier 30, and causes the liquid supplier 30 to stop the supply of the resist liquid before the resist liquid supplied to the front surface Wa reaches the outer periphery Wc.

The first coating controller 114 may control the liquid supplier 30 so that, when the resist liquid is supplied to the center of the front surface Wa by the liquid supplier 30, the nozzle 31 discharges the resist liquid having a viscosity of 5 cP or less at a flow rate of 0.2 cc or less per second. The first coating speed is, for example, 1000 to 3000 rpm.

The timing at which the first coating controller 114 stops the discharge of the resist liquid by the liquid supplier 30 may be set such that the position where the resist liquid reaches at that timing is 0.4 to 1.0 times (0.4 to 0.9 times, or 0.4 to 0.8 times) of the radius of the wafer W from the center of the wafer W. The timing at which the first coating controller 114 stops the discharge of the resist liquid by the liquid supplier 30 may be set such that the resist liquid reaches the aforementioned annular region (the region to which the cooling fluid is supplied) at the timing.

The first coating controller 114 may reduce the rotation speed of the wafer W by the rotary holder 20 to a predetermined rotation speed (hereinafter referred to as “reflow speed”) lower than the first coating speed at the timing of stopping the discharge of the resist by the liquid supplier 30. For example, the first coating controller 114 reduces the rotation speed of the wafer W by the rotary holder 20 to the reflow speed before stopping the discharge of the resist liquid. The first coating controller 114 may reduce the rotation speed of the wafer W by the rotary holder 20 to the reflow speed simultaneously with stopping the discharge of the resist liquid. Furthermore, the first coating controller 114 may reduce the rotation speed of the wafer W by the rotary holder 20 to the reflow speed after stopping the discharge of the resist liquid. The reflow speed is, for example, 5 to 200 rpm.

The nozzle transport controller 111 controls the nozzle transporter 60 to arrange the nozzle 41 above the center of the wafer W by the horizontal transporter 61 before the pre-wetting liquid is supplied from the nozzle 41 to the front surface Wa of the wafer W. Thereafter, the nozzle transport controller 111 controls the nozzle transporter 60 so that the elevator 62 brings the nozzle 41 close to the front surface Wa.

After supplying the pre-wetting liquid from the nozzle 41 to the front surface Wa of the wafer W, the nozzle transport controller 111 controls the nozzle transporter 60 so that the elevator 62 moves the nozzle 41 away from the front surface Wa. Thereafter, the nozzle transport controller 111 controls the nozzle transporter 60 so that the horizontal transporter 61 retracts the nozzle 41 from above the wafer W.

After coating the pre-wetting liquid on the front surface Wa of the wafer W and before supplying the resist liquid to the front surface Wa, the nozzle transport controller 112 controls the nozzle transporter 50 so that the horizontal transporter 51 arranges the nozzle 31 above the center of the wafer W. Thereafter, the nozzle transport controller 112 controls the nozzle transporter 50 so that the elevator 52 brings the nozzle 31 close to the front surface Wa until the spacing between the front surface Wa and the nozzle 31 becomes a predetermined coating spacing. The coating spacing may be set so that the resist liquid can be held between the nozzle 31 and the front surface Wa when the discharge of the resist liquid from the nozzle 31 is stopped. For example, the coating spacing may be 3 times or less of the inner diameter of the nozzle 31, or may be 2 times or less of the inner diameter of the nozzle 31.

After supplying the resist liquid from the nozzle 31 to the front surface Wa of the wafer W, the nozzle transport controller 112 controls the nozzle transporter 50 so that the elevator 52 moves the nozzle 31 away from the front surface Wa. Thereafter, the nozzle transport controller 112 controls the nozzle transporter 50 so that the horizontal transporter 51 retracts the nozzle 31 from above the wafer W. For example, the nozzle transport controller 112 causes the nozzle transporter 50 to move the nozzle 31 away from the front surface Wa while the wafer W is rotating at the reflow speed.

After the supply of the resist liquid by the liquid supplier 30 is stopped, the second coating controller 115 causes the rotary holder 20 to continuously rotate the wafer W at the second rotation speed (hereinafter referred to as “second coating speed”). The second coating speed is higher than the reflow speed. For example, the second coating controller 115 increases the rotation speed of the wafer W by the rotary holder 20 from the reflow speed to the second coating speed after the rotation of the wafer W at the reflow speed continues for a predetermined period, and then causes the rotary holder 20 to continuously rotate the wafer W at the second coating speed for a predetermined period. The second coating speed may be lower than the first coating speed. The second coating speed is, for example, 500 to 2500 rpm.

The cooling controller 116 causes the cooling fluid supplier 80 to supply a cooling fluid to the outer peripheral portion of the rear surface Wb of the wafer W during a supply period including at least a part of the period from after the supply of the resist liquid is stopped by the liquid supplier 30 until the rotation of the wafer W at the second coating speed is completed. The cooling controller 116 may start the supply of the cooling fluid by the cooling fluid supplier 80 after the supply of the resist liquid by the liquid supplier 30 is stopped.

The cooling controller 116 may stop the supply of the cooling fluid by the cooling fluid supplier 80 before the rotation of the wafer W at the second coating speed is stopped. The cooling controller 116 may stop the supply of the cooling fluid by the cooling fluid supplier 80 before one half of the rotation period of the wafer W at the second coating speed (hereinafter referred to as “second coating period”) is elapsed. The cooling controller 116 may stop the supply of the cooling fluid by the cooling fluid supplier 80 before ¼ of the second coating period elapses, or may stop the supply of the cooling fluid by the cooling fluid supplier 80 before ⅛ of the second coating period elapses.

The cooling controller 116 may supply the cooling fluid to the outer peripheral portion of the rear surface Wb at a flow rate (supply volume per unit time) smaller than the exhaust amount of the gas from the exhaust port 74a (exhaust volume per unit time). The flow rate of the cooling fluid means the total flow rate of the cooling liquid and the cooling gas.

The coating condition storage 121 stores the execution conditions of the above-described coating control by the coating controller 110 (hereinafter referred to as “coating conditions”). Specific examples of the coating conditions include the first pre-wetting rate, the second pre-wetting rate, the first coating rate, the reflow rate, the second coating rate, and the supply period. The transfer controller 122 controls the transfer arm A3 so as to transfer the wafer W to which the resist liquid is to be coated. The transfer controller 122 may control the transfer arm A3 so as to load the wafer W into the substrate cooler 91 prior to loading the wafer W into the coating unit U1. As a result, the wafer W is cooled prior to the processing performed by the coating unit U1. The transfer controller 122 may control the transfer arm A3 so that the wafer W unloaded from the coating unit U1 is loaded into the surface inspector 92.

The controller 100 may be configured to automatically set at least a part of the coating conditions stored in the coating condition storage 121. For example, the controller 100 further includes a film thickness data acquisitor 123, a basic condition storage 124, and a condition setting unit 125, as functional modules.

The film thickness data acquisitor 123 acquires film thickness information from the surface inspector 92. The basic condition storage 124 stores plural types of coating conditions preset for each type of resist liquid. The condition setting unit 125 selects coating conditions corresponding to the type of resist liquid from a plurality of coating conditions stored in the coating condition storage 121, and automatically adjusts at least a part of the selected coating conditions (hereinafter referred to as “basic condition”). For example, the condition setting unit 125 automatically adjusts at least the first coating speed and the supply period among the basic conditions.

As an example, the condition setting unit 125 repeats sample preparation and sample measurement while changing a combination of the first coating speed and the supply period, until a variation in film thickness on a wafer W for condition setting (sample substrate) becomes equal to or lower than a predetermined level, wherein the sample preparation includes rotating the sample substrate at a first coating speed while supplying a resist liquid to a center of a front surface Wa of the sample substrate, stopping the supply of the resist liquid before the resist liquid supplied to the front surface Wa of the sample substrate reaches an outer periphery We of the sample substrate, continuing to rotate the sample substrate at a second coating speed after the supply of the resist liquid is stopped, and supplying a cooling fluid to an outer peripheral portion of a rear surface Wb of the sample substrate during the supply period, and wherein the sample measurement includes measuring a film thickness of a film formed on the front surface Wa of the sample substrate by the sample preparation.

In the sample preparation, the condition setting unit 125 causes the coating controller 110 to execute the coating control on the sample substrate. In the sample measurement, the condition setting unit 125 acquires, from the surface inspector 92 by the film thickness data acquisitor 123, film thickness information of the sample substrate loaded into the surface inspector 92. Furthermore, the condition setting unit 125 controls the transfer arm A3 through the use of the transfer controller 122 so as to transfer the sample substrate that serves as a target of the sample preparation and the sample measurement.

The act of repeating the sample preparation and the sample measurement may include reducing the variation in the film thickness on the sample substrate by changing the first coating speed while setting the supply period to a predetermined value. For example, the act of repeating the sample preparation and the sample measurement may include bringing the variation in the film thickness on the sample substrate close to a minimum value by repeating the sample preparation and the sample measurement while setting the supply period to a predetermined value and changing the first coating speed. The predetermined value here may be changed each time when a sample is prepared. The act of repeating the sample preparation and the sample measurement may include reducing the variation in the film thickness on the sample substrate by setting the first coating speed to a predetermined value and changing the supply period. For example, the act of repeating the sample preparation and the sample measurement may include bringing the variation in the film thickness of the sample substrate close to a quartic or higher even-order function by changing the supply period while setting the first coating speed to a predetermined value. The act of repeating the sample preparation and the sample measurement may include bringing a film thickness distribution on the sample substrate close to a quartic function by repeating the sample preparation and the sample measurement while setting the first coating speed to a predetermined value and changing the supply period. The predetermined value here may be changed each time when a sample is prepared.

The condition setting unit 125 may execute: preparing a plurality of sample substrates by repeating the sample preparation while changing a combination of the first coating speed and the supply period; measuring the film thickness of the coating film formed on the front surface Wa of each of the plurality of sample substrates (i.e., performing the “sample measurement”); and setting the first coating speed and the supply period so as to reduce the variation in the film thickness based on the variation in the film thickness on each of the plurality of sample substrates. For example, the condition setting unit 125 may express the relationship of the variation in the film thickness, the first coating speed, and the supply period as a function based on the variation in the film thickness on each of the plurality of sample substrates, and may derive a first coating speed and a supply period for bringing the variation in the film thickness close to a minimum value, based on the obtained function.

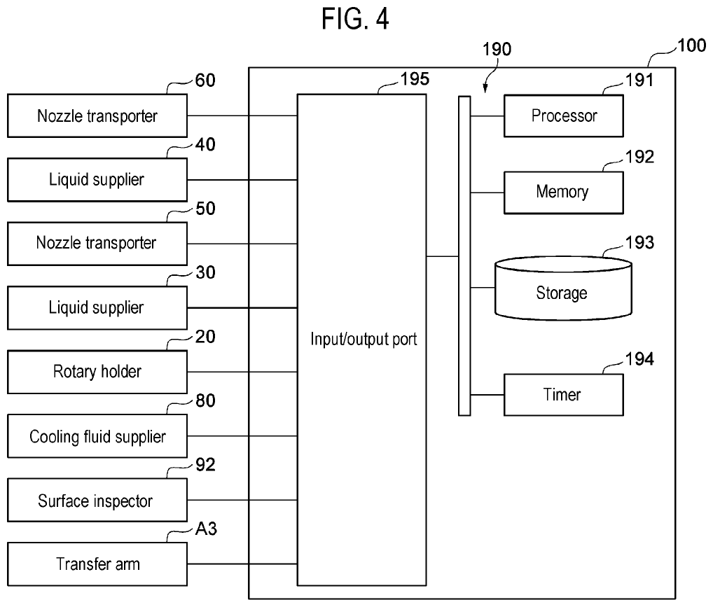

FIG. 4 is a block diagram showing a hardware configuration of the controller 100. The controller 100 is composed of one or a plurality of control computers. As shown in FIG. 4, the controller 100 includes a circuit 190. The circuit 190 includes at least one processor 191, a memory 192, a storage 193, a timer 194, and an input/output port 195. The storage 193 includes a computer-readable storage medium such as a hard disk or the like. The storage 193 stores a program for causing the controller 100 to execute: rotating the wafer W by the rotary holder 20 at a first coating speed while supplying the resist liquid to the center of the front surface Wa of the wafer W by the liquid supplier 30; stopping the supply of the resist liquid by the liquid supplier 30 before the resist liquid supplied to the front surface Wa reaches the outer periphery We of the wafer W; continuing to rotate the wafer W by the rotary holder 20 at a second coating speed after the supply of the resist liquid by the liquid supplier 30 is stopped; and supplying the cooling fluid to the outer peripheral portion of the rear surface Wb by the cooling fluid supplier 80 during a supply period including at least a part of a period from the time when the supply of the resist liquid by the liquid supplier 30 is stopped to the time when the rotation of the wafer W at the second coating speed is completed. For example, the storage 193 may store a program for forming each functional module of the controller 100 described above by the controller 100.

The memory 192 temporarily stores the program loaded from the storage medium of the storage 193 and the calculation result of the processor 191. The processor 191 forms each functional module described above by executing the program in cooperation with the memory 192. The timer 194 measures the elapsed time by counting, for example, reference pulses having a constant cycle. The input/output port 195 inputs and outputs electrical signals to and from the rotary holder 20, the liquid suppliers 30 and 40, the nozzle transporters 50 and 60, the cooling fluid supplier 80, the surface inspector 92, and the transfer arm A3 in response to a command from the processor 191.

The hardware configuration of the controller 100 is not necessarily limited to formation of each functional module by the program. For example, at least a part of the functional modules of the controller 100 may be configured by a dedicated logic circuit or an ASIC (Application Specific Integrated Circuit) in which the logic circuit is integrated.

### [Coating Procedure]

Hereinafter, as an example of a coating method, a coating procedure executed in the processing module 12 will be described. This coating procedure includes: rotating the wafer W at a first coating speed while supplying the resist liquid to the center of the front surface Wa of the wafer W; stopping the supply of the resist liquid before the resist liquid supplied to the front surface Wa reaches the outer periphery We of the wafer W; continuing to rotate the wafer W at a second coating speed after the supply of the resist liquid is stopped; and supplying the cooling fluid to the outer peripheral portion of the rear surface Wb of the wafer W during a supply period including at least a part of a period from the time when the supply of the resist liquid is stopped to the time when the rotation of the wafer W at the second coating speed is completed.

In the coating unit U1 described above, the supply of the cooling fluid by the cooling fluid supplier 80 is performed in a state in which the gas in the cup 70 is exhausted to the outside of the cup 70 by the exhaust portion 74. Accordingly, the coating procedure in the coating unit U1 further includes: discharging the gas in the accommodation space of the wafer W from the exhaust port 74a below the rear surface Wb of the wafer W at least when the cooling fluid is supplied to the outer peripheral portion of the rear surface Wb of the wafer W.

Furthermore, in the coating unit U1 described above, the resist liquid is supplied from the liquid source 32 to the nozzle 31 through the throttle portion 35 and the valve 33. Accordingly, the act of supplying the resist liquid to the center of the front surface Wa of the wafer W includes supplying a film-forming liquid to the nozzle 31 from the liquid source 32 through the throttle portion 35 and the valve 33. Moreover, in the coating unit U1 described above, the resist liquid is cooled in the tank of the liquid source 32. Accordingly, the coating procedure in the coating unit U1 includes cooling the resist liquid supplied to the wafer W.

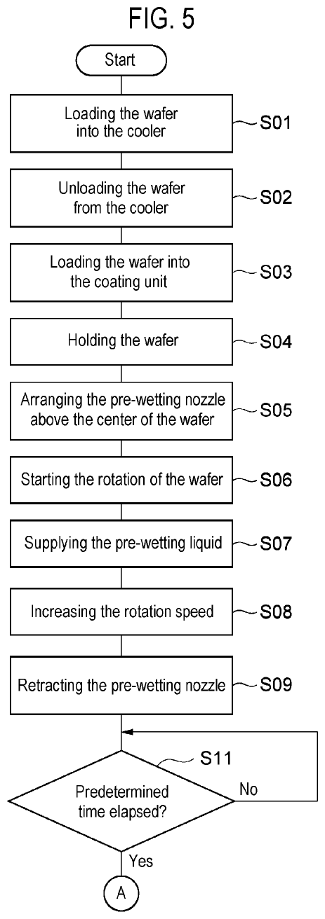

As shown in FIG. 5, the controller 100 first sequentially executes steps S01, S02, S03, S04, S05, S06, S07, S08, S09, and S11 in this order. In step S01, the transfer controller 122 controls the transfer arm A3 so as to load the wafer W into the substrate cooler 91. In step S02, the transfer controller 122 controls the transfer arm A3 so as to unload the wafer W from the substrate cooler 91. In step S03, the transfer controller 122 controls the transfer arm A3 so as to load the wafer W unloaded from the substrate cooler 91 into the coating unit U1 and mount the wafer W on the holder 21.

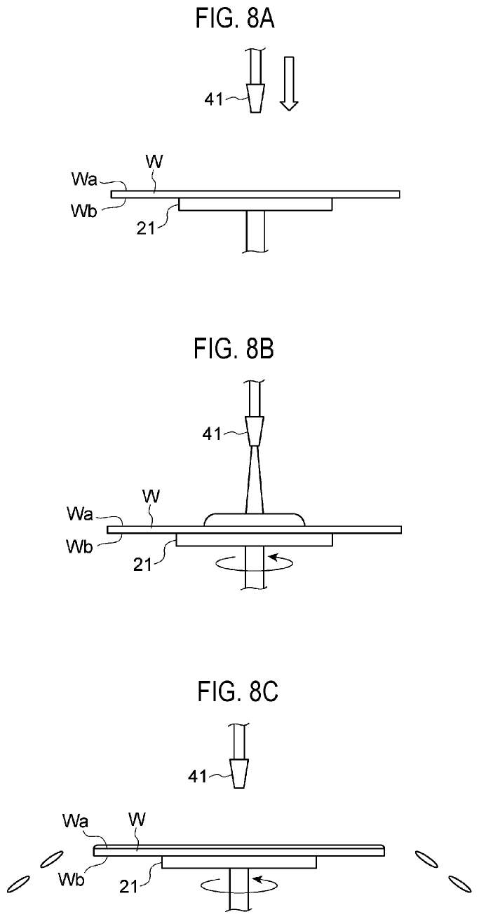

In step S04, the transfer controller 122 controls the rotary holder 20 so that the wafer W mounted on the holder 21 by the transfer arm A3 is held by the holder 21. In step S05, the nozzle transport controller 111 controls the nozzle transporter 60 so that the horizontal transporter 61 arranges the nozzle 41 above the center of the wafer W. Thereafter, the nozzle transport controller 111 controls the nozzle transporter 60 so that the nozzle 41 is brought close to the front surface Wa by the elevator 62 (see FIG. 8A).

In step S06, the pre-wetting controller 113 causes the rotary holder 20 to start rotating the wafer W at a first pre-wetting speed oil. In step S07, the pre-wetting controller 113 causes the liquid supplier 40 to supply a predetermined amount of pre-wetting liquid to the front surface Wa of the wafer W (see FIG. 8B). In step S08, the pre-wetting controller 113 causes the rotary holder 20 to increase the rotation speed of the wafer W from the first pre-wetting speed ω1 to a second pre-wetting speed ω2. As a result, the pre-wetting liquid supplied from the nozzle 41 to the front surface Wa of the wafer W spreads toward the outer periphery We of the wafer W under a centrifugal force, and the excess pre-wetting liquid is shaken off around the wafer W (see FIG. 8C).

In step S09, the nozzle transport controller 111 controls the nozzle transporter 60 so that the elevator 62 moves the nozzle 41 away from the front surface Wa and the horizontal transporter 61 retracts the nozzle 41 from above the wafer W. In step S11, the pre-wetting controller 113 waits for a predetermined time to elapse from the timing at which the wafer W starts rotating at the second pre-wetting speed ω2. The predetermined time is set by a preliminary actual machine test or simulation so that the excess pre-wetting liquid is sufficiently shaken off.

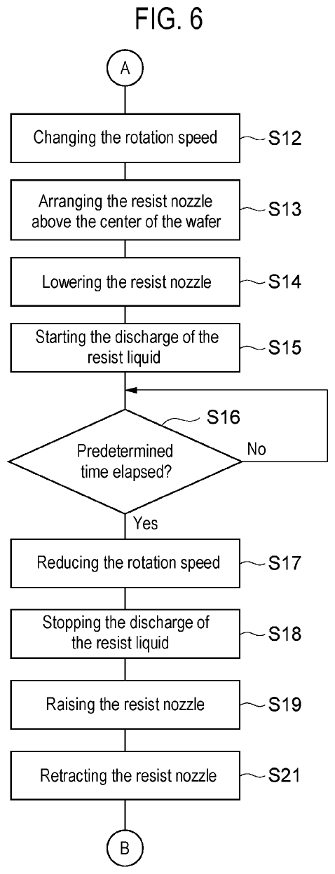

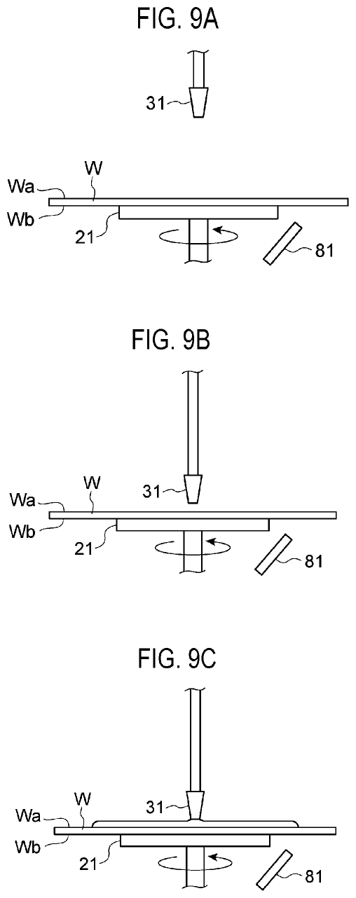

Next, the controller 100 sequentially executes steps S12, S13, S14, S15, S16, S17, S18, S19, and S21 as shown in FIG. 6. In step S12, the first coating controller 114 causes the rotary holder 20 to change the rotation speed of the wafer W from the second pre-wetting speed ω2 to a first coating speed ω3. In step S13, the nozzle transport controller 112 controls the nozzle transporter 50 so that the horizontal transporter 51 arranges the nozzle 31 above the center of the wafer W (see FIG. 9A). In step S14, the nozzle transport controller 112 controls the nozzle transporter 50 so that the nozzle 31 is brought close to the front surface Wa by the elevator 52 until the spacing between the front surface Wa and the nozzle 31 becomes the aforementioned coating spacing (see FIG. 9B).

In step S15, the first coating controller 114 causes the liquid supplier 30 to start supplying the resist liquid from the nozzle 31 to the front surface Wa of the wafer W in a state in which the spacing between the front surface Wa of the wafer W and the nozzle 31 is maintained at the aforementioned coating spacing (see FIG. 9C). In step S16, the first coating controller 114 waits for a predetermined time to elapse from the timing at which the discharge of the resist liquid from the nozzle 31 is started. The predetermined time is set by a preliminary actual machine test or simulation so that the resist liquid can be supplied in an amount sufficient to make the film thickness of the resist film equal to the target film thickness.

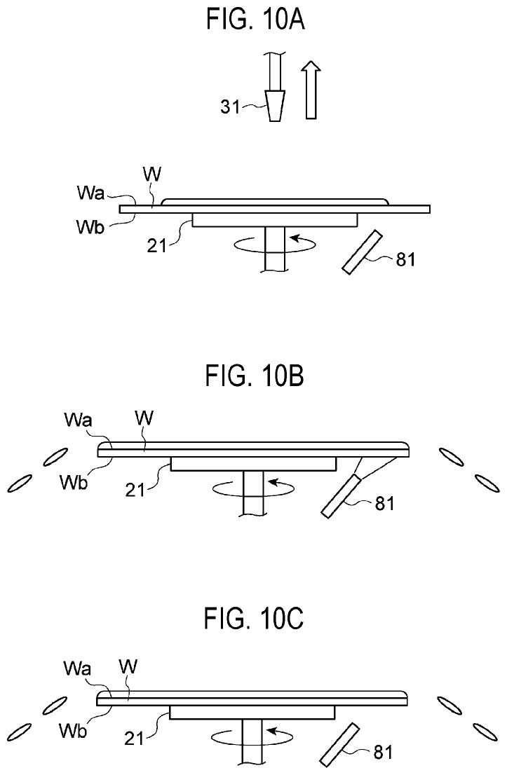

In step S17, the first coating controller 114 causes the rotary holder 20 to reduce the rotation speed of the wafer W from the first coating speed ω3 to a reflow speed ω4. In step S18, the first coating controller 114 causes the liquid supplier 30 to stop the discharge of the resist liquid from the nozzle 31. In step S19, the nozzle transport controller 112 controls the nozzle transporter 50 so that the elevator 52 moves the nozzle 31 away from the front surface Wa (see FIG. 10A). In step S21, the nozzle transport controller 112 controls the nozzle transporter 50 so that the horizontal transporter 51 retracts the nozzle 31 from above the wafer W.

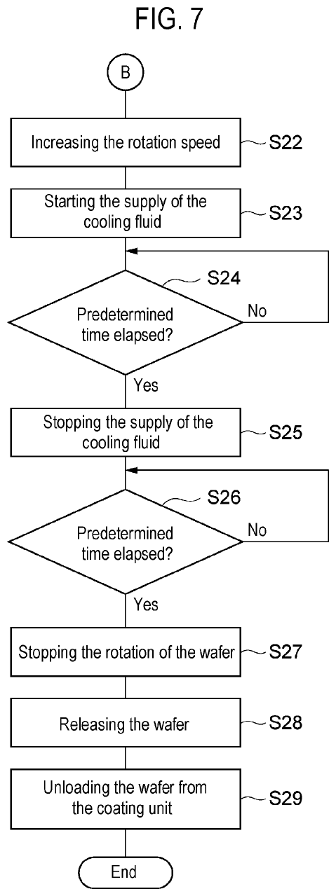

Next, the controller 100 executes steps S22, S23, S24, S25, S26, S27, S28, and S29 as shown in FIG. 7. In step S22, the second coating controller 115 causes the rotary holder 20 to increase the rotation speed of the wafer W from the reflow speed ω4 to a second coating speed ω5. In step S23, the cooling controller 116 causes the cooling fluid supplier 80 to start the supply of the cooling fluid (see FIG. 10B).

In step S24, the cooling controller 116 waits until a predetermined time elapses from the timing at which the wafer W starts rotating at the second coating speed ω5. The predetermined time is set by a preliminary actual machine test, simulation, or the like from the viewpoint of improving the uniformity of the film thickness of the resist film. In step S25, the cooling controller 116 causes the cooling fluid supplier 80 to stop the supply of the cooling fluid from the spray nozzle 81 to the rear surface Wb of the wafer W.

In step S26, the second coating controller 115 waits until a predetermined time elapses from the timing at which the wafer W starts rotating at the second coating speed. During this time, the resist liquid continues to spread toward the outer periphery Wc, and the excess resist liquid is shaken off from the front surface Wa (see FIG. 10C). The predetermined time is set by a preliminary actual machine test, simulation, or the like from the viewpoint of improving the uniformity of the film thickness of the resist film. In step S27, the first coating controller 114 causes the rotary holder 20 to stop the rotation of the wafer W.

In step S28, the transfer controller 122 controls the rotary holder 20 so that the holder 21 releases the wafer W. In step S29, the transfer controller 122 controls the transfer arm A3 so as to unload the wafer W from the coating unit U1. Thereafter, the transfer controller 122 may control the transfer arm A3 so as to load the wafer W unloaded out of the coating unit U1 into the surface inspector 92. Thus, the coating procedure is completed.

### [Coating Condition Setting Procedure]

As described above, the controller 100 may be configured to automatically set at least a part of the coating conditions stored in the coating condition storage 121. Hereinafter, the coating condition setting procedure will be exemplified.

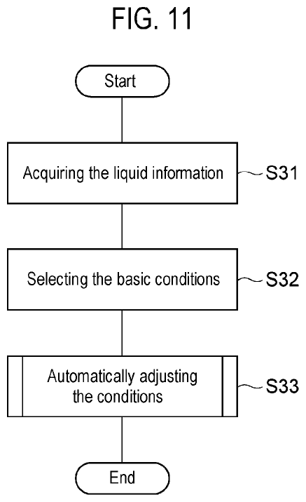

As shown in FIG. 11, the controller 100 sequentially executes steps S31, S32, and S33. In step S31, the condition setting unit 125 acquires information indicating the type of resist liquid. The information indicating the type of resist liquid is inputted to the controller 100 by, for example, an operator. In step S32, the condition setting unit 125 selects coating conditions (basic conditions) corresponding to the type of resist liquid from the plurality of coating conditions stored in the coating condition storage 121. In step S33, the condition setting unit 125 automatically adjusts at least a part of the basic conditions. For example, the condition setting unit 125 automatically adjusts the first coating speed and the supply period among the basic conditions. Thus, the coating condition setting procedure is completed.

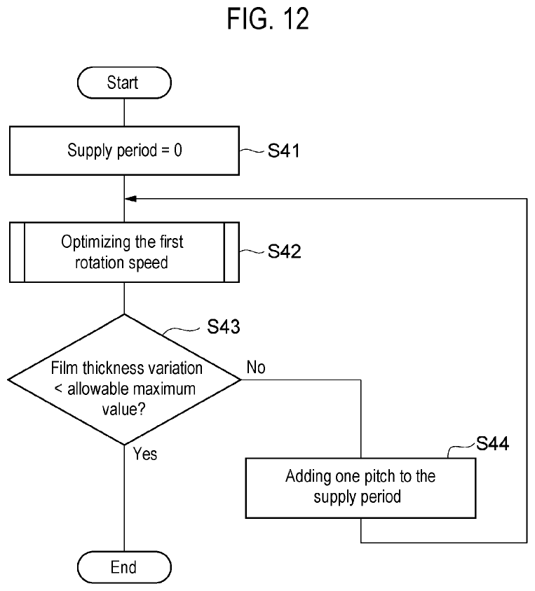

FIG. 12 is a flowchart illustrating the automatic adjustment procedure of the first coating speed and the supply period performed in step S33. As shown in FIG. 12, the controller 100 first executes steps S41, S42, and S43. In step S41, the condition setting unit 125 sets the supply period of the basic conditions to zero. In step S42, the condition setting unit 125 sets the first coating speed (first rotation speed) so that the variation in the film thickness on the sample substrate is brought close to a minimum value. Hereinafter, this will be referred to as “first coating speed optimization.” A specific example of the procedure for first coating speed optimization will be described later. In step S43, the condition setting unit 125 determines whether or not the variation in film thickness at the first coating speed set in step S42 is less than an allowable maximum value.

If it is determined in step S43 that the variation in the film thickness is equal to or larger than the allowable maximum value, the controller 100 executes step S44. In step S44, the condition setting unit 125 adds a preset adjustment value for one pitch to the supply period of the basic conditions. Thereafter, the controller 100 returns the process to step S42. Then, the change of the supply period and the first coating speed optimization for the changed supply period are repeated until the variation in the film thickness becomes less than the allowable maximum value. If it is determined in step S43 that the variation in film thickness is less than the maximum allowable value, the automatic adjustment of the first coating speed and the supply period is completed.

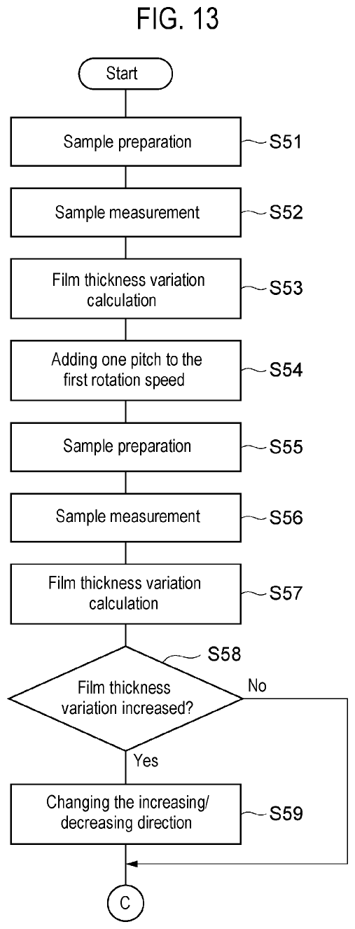

FIG. 13 is a flowchart illustrating the procedure for first coating speed optimization. As shown in FIG. 13, the controller 100 first executes steps S51, S52, S53, S54, S55, S56, S57, and S58. In step S51, the condition setting unit 125 causes the transfer controller 122 to control the transfer arm A3 so as to transfer the sample substrate from the substrate cooler 91 to the coating unit U1, and causes the coating controller 110 to execute the above-described coating control for the sample substrate.

In step S52, the condition setting unit 125 causes the transfer controller 122 to control the transfer arm A3 so as to transfer the sample substrate subjected to the coating control to the surface inspector 92, and causes the film thickness data acquisitor 123 to acquire from the surface inspector 92 the film thickness information of the sample substrate loaded into the surface inspector 92.

In step S53, the condition setting unit 125 calculates the film thickness variation based on the film thickness information acquired in step S52. For example, the condition setting unit 125 calculates the film thickness variation based on the standard deviation of the film thicknesses at a plurality of locations on the sample substrate. More specifically, the condition setting unit 125 calculates three times the standard deviation as a numerical value indicating the film thickness variation.

In step S54, the condition setting unit 125 adds a preset adjustment value for one pitch to the first coating speed (first rotation speed). In steps S55, S56, and S57, the condition setting unit 125 performs the same processing as in steps S51, S52, and S53 on the next sample substrate, and calculates the film thickness variation for the sample substrate. In step S58, the condition setting unit 125 determines whether or not the variation in the film thickness calculated in step S57 has increased from the variation in the film thickness calculated in step S53.

If it is determined in step S58 that the variation in the film thickness calculated in step S57 has increased from the variation in the film thickness calculated in step S53, the controller 100 executes step S59. In step S59, the condition setting unit 125 changes the increasing/decreasing direction of the first coating speed by adding the adjustment value. For example, the condition setting unit 125 reverses the sign of the adjustment value.

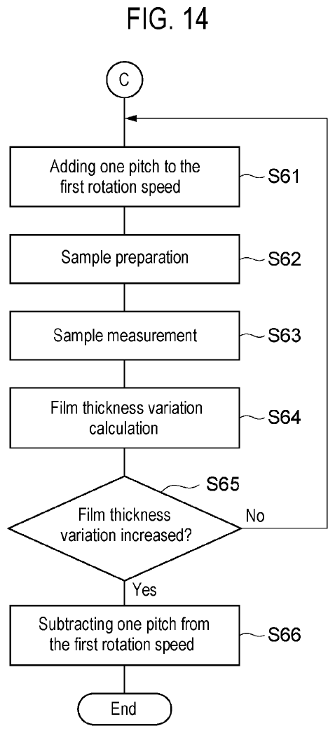

As shown in FIG. 14, the controller 100 then executes step S61. If it is determined in step S58 that the variation in the film thickness calculated in step S57 has not increased from the variation in the film thickness calculated in step S53, the controller 100 executes step S61 without executing step S59. In step S61, the condition setting unit 125 adds a preset adjustment value for one pitch to the first coating speed.

The controller 100 then executes steps S62, S63, S64, and S65. In steps S62, S63, and S64, the condition setting unit 125 executes the same processing as in steps S51, S52, and S53 on the next sample substrate, and calculates the film thickness variation for the next sample substrate. In step S65, the condition setting unit 125 determines whether or not the variation in the film thickness of the next sample substrate has increased from the previously calculated variation in the film thickness.

If it is determined in step S65 that the variation in the film thickness of the next sample substrate has not increased from the previously calculated variation in the film thickness, the controller 100 returns the process to step S61. Thereafter, as long as the variation in the film thickness decreases, the addition of the adjustment value to the first coating speed, the sample preparation, the sample measurement, and the calculation of the film thickness variation are repeated.

If it is determined in step S65 that the variation in the film thickness of the next sample substrate is larger than the previously calculated variation in the film thickness, the controller 100 executes step S66. In step S66, the condition setting unit 125 subtracts the adjustment value for one pitch from the first coating speed. Thus, the procedure for first coating speed optimization is completed.

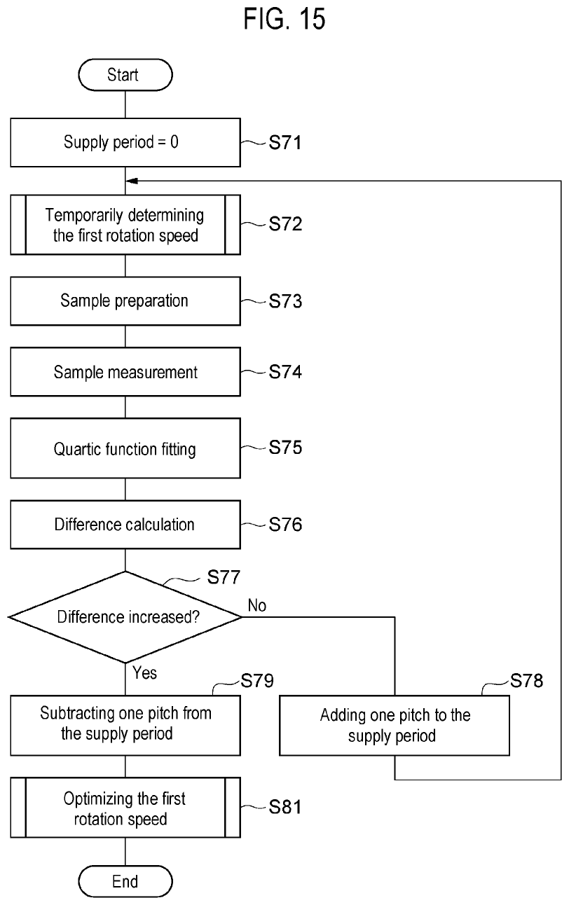

FIG. 15 is a flowchart showing a modification of the automatic adjustment procedure of the first coating speed and the supply period performed in step S33. As shown in FIG. 15, the controller 100 first executes steps S71, S72, S73, S74, S75, S76, and S77. In step S71, the condition setting unit 125 sets the supply period of the basic conditions to zero. In step S72, the condition setting unit 125 temporarily determines the first coating speed so as to facilitate the supply period optimization described later. The procedure for temporarily determining the first coating speed will be described later. In step S73, the condition setting unit 125 performs sample preparation as in step S51. In step S74, the condition setting unit 125 performs sample measurement as in step S52.

In step S75, the condition setting unit 125 performs quartic function fitting on the film thickness distribution obtained in the sample measurement. Specifically, the condition setting unit 125 derives a quartic function that most closely approximates the relationship between the distance from the center of the wafer W and the film thickness (hereinafter referred to as “film thickness profile”). In step S76, the condition setting unit 125 derives the difference between the film thickness profile and the quartic function.

In step S75, a quartic function may be fitted to a partial region of the film thickness profile. In step S76, the difference between the film thickness profile and the quartic function may be derived outside the partial region. For example, in step S75, the condition setting unit 125 derives a quartic function that most closely approximates the film thickness profile in the range from the center of the wafer W to a predetermined position near the outer periphery Wc. In this case, in step S76, the condition setting unit 125 derives the difference between the film thickness profile and the quartic function outside the predetermined position. The condition setting unit 125 may perform quartic function fitting on the entire region of the film thickness profile and calculate the sum of squares or the square root of the sum of squares of the entire region difference between the film thickness profile and the quartic function.

In step S77, the condition setting unit 125 determines whether or not the difference between the film thickness profile and the quartic function has increased from the previously calculated difference.

If it is determined in step S77 that the difference between the film thickness profile and the quartic function has not increased from the previously calculated difference, the controller 100 executes step S78. In step S78, the condition setting unit 125 adds an adjustment value for one pitch to the supply period. Thereafter, the controller 100 returns the process to step S72. Then, as long as the difference between the film thickness profile and the quartic function decreases, the addition of the adjustment value to the supply period, the sample preparation, the sample measurement, the quartic function fitting, and the difference derivation are repeated.

If it is determined in step S77 that the difference between the film thickness profile and the quartic function is larger than the previously calculated difference, the controller 100 executes step S79. In step S79, the condition setting unit 125 subtracts the adjustment value for one pitch from the supply period. Through steps S71 to S79, the supply period is set so that the difference between the film thickness profile and the quartic function approaches a minimum value. Hereinafter, this will be referred to as “supply period optimization.”

Next, the controller 100 executes step S81. In step S81, the condition setting unit 125 optimizes the first coating speed for the supply period set by the supply period optimization. The procedure for first coating speed optimization is the same as the procedure illustrated in FIGS. 13 and 14. Thus, the automatic adjustment of the first coating speed and the supply period is completed.

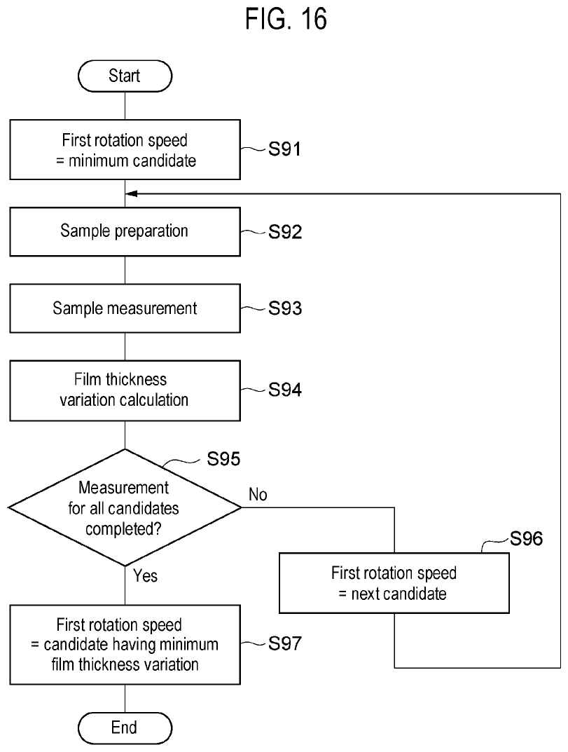

FIG. 16 is a flowchart illustrating a procedure for temporarily determining the first coating speed in step S72. This procedure is executed in a state in which a plurality of first coating speed candidates is predetermined. As shown in FIG. 16, the controller 100 first executes steps S91, S92, S93, S94, and S95. In step S91, the condition setting unit 125 sets the first coating speed to the smallest candidate among the plurality of candidates. In steps S92, S93, and S94, the condition setting unit 125 executes the same process as in steps S51, S52, and S53 on the next sample substrate, and calculates the film thickness variation on the next sample substrate. In step S95, the condition setting unit 125 determines whether or not the sample preparation, the sample measurement, and the film thickness variation calculation have been completed for all candidates.

If it is determined in step S95 that there remains a candidate for which the sample preparation, the sample measurement, and the film thickness variation calculation have not been completed, the controller 100 executes step S96. In step S96, the condition setting unit 125 sets the first coating speed to the next candidate among the plurality of candidates. Thereafter, the controller 100 returns the process to step S92. Then, the change of the first coating speed, the sample preparation, the sample measurement, and the film thickness variation calculation are repeated until the film thickness variation calculation is completed for all the candidates.

If it is determined in step S95 that the sample preparation, the sample measurement, and the film thickness variation calculation have been completed for all candidates, the controller 100 executes step S97. The condition setting unit 125 temporarily determines the first coating speed to a candidate having the smallest variation in the film thickness. Thus, the procedure for temporarily determining the first coating speed is completed.

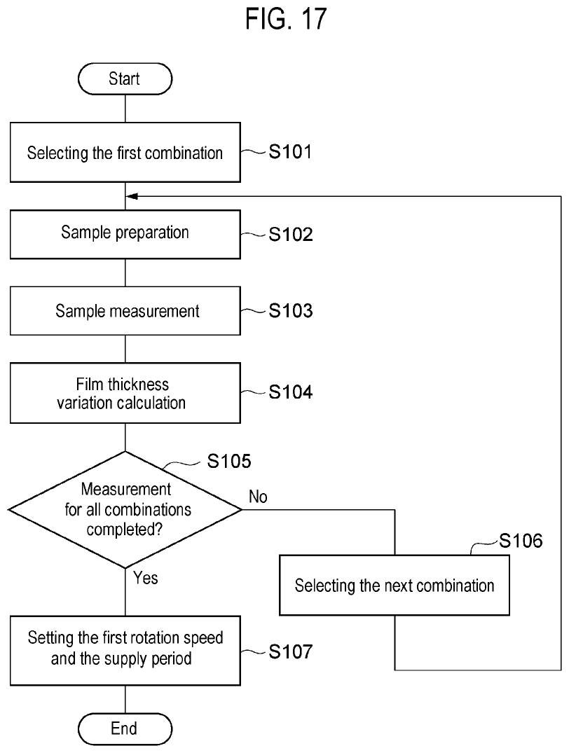

FIG. 17 is a flowchart showing a modification of the automatic adjustment procedure of the first coating speed and the supply period performed in step S33. This procedure is executed in a state where a plurality of combinations of the first coating speed and the supply period is predetermined. As shown in FIG. 17, the controller 100 first executes steps S101, S102, S103, S104, and S105. In step S101, the condition setting unit 125 selects the first combination from the plurality of combinations. In steps S102, S103, and S104, the condition setting unit 125 performs the same process as in steps S51, S52, and S53 on the next sample substrate, and calculates the variation in the film thickness for the next sample substrate. In step S105, the condition setting unit 125 determines whether or not the sample preparation, the sample measurement, and the film thickness variation calculation have been completed for all combinations.

If it is determined in step S105 that there remains a combination for which the sample preparation, the sample measurement, and the film thickness variation calculation have not been completed, the controller 100 executes step S106. In step S106, the condition setting unit 125 selects the next combination from the plurality of combinations. Thereafter, the controller 100 returns the process to step S102. Then, the selection of the next combination, the sample preparation, the sample measurement, and the film thickness variation calculation are repeated until the film thickness variation calculation is completed for all combinations.

If it is determined in step S105 that the sample preparation, the sample measurement, and film thickness variation calculation have been completed for all combinations, the controller 100 executes step S107. In step S107, the condition setting unit 125 sets the first coating speed and the supply period so as to reduce the variation in the film thickness based on the variation in the film thickness in each of the plurality of combinations. For example, the condition setting unit 125 may express the relationship between the variation in the film thickness and the first coating speed and the supply period as a function based on the variation in the film thickness on each of the plurality of combinations, and may derive a first coating speed and a supply period for bringing the variation in the film thickness close to a minimum value, based on the obtained function. Thus, the automatic adjustment of the first coating speed and the supply period is completed.

### Effects of the Present Embodiment

As described above, the coating method includes: rotating the wafer W at a first coating speed while supplying the film-forming liquid to the center of the front surface Wa of the wafer W; stopping the supply of the film-forming liquid before the film-forming liquid supplied to the front surface Wa reaches the outer periphery Wc of the wafer W; continuing to rotate the wafer W at a second coating speed after the supply of the film-forming liquid is stopped; and supplying the cooling fluid as a gas-liquid mixture to the outer peripheral portion of the rear surface Wb of the wafer W during a supply period including at least a part of a period from the time when the supply of the film-forming liquid is stopped to the time when the rotation of the wafer W at the second coating speed is completed.

According to the coating method, by rotating the wafer W at the first coating speed while supplying the film-forming liquid to the center of the front surface Wa of the wafer W and stopping the supply of the film-forming liquid before the film-forming liquid supplied to the front surface Wa reaches the outer periphery Wc of the wafer W, a liquid film of the film-forming liquid is formed in a region inside the outer periphery Wc of the wafer W. Thereafter, by rotating the wafer W at the second coating speed, the liquid film is spread to the outer periphery Wc of the wafer W.

As the wafer W rotates, the outer peripheral portion of the liquid film moves faster than the central portion of the liquid film. Therefore, as compared with the central portion of the liquid film, in the outer peripheral portion of the liquid film, the film-forming liquid is easily dried, and the fluidity of the liquid film easily decreases. When the fluidity of the liquid film in the outer peripheral portion is lower than that in the central portion, the film-forming liquid in the liquid film is biased toward the outer peripheral portion, which may reduce the in-plane uniformity of the film thickness. In particular, after the supply of the film-forming liquid is stopped, a decrease in the fluidity of the liquid film in the outer peripheral portion and a decrease in the in-plane uniformity of the film thickness caused by the decrease in the fluidity are likely to occur.

In contrast, according to the present coating method, the cooling fluid of a gas-liquid mixture is supplied to the outer peripheral portion of the rear surface Wb of the wafer W during at least a part of the period from the time when the supply of the film-forming liquid is stopped to the time when the rotation of the wafer W at the second coating speed is completed. As a result, the outer peripheral portion of the wafer W is efficiently cooled. Therefore, even after the supply of the film-forming liquid is stopped, the decrease in the fluidity in the outer peripheral portion is suppressed. Accordingly, the present coating method is effective for improving the in-plane uniformity of the film thickness.

In order to verify the effects of the present embodiment, the following two samples were prepared and the variations in film thickness were compared.

Sample 1) A resist film was formed on the front surface Wa of the wafer W according to the procedure of steps S01 to S29 described above. The flow rate of the resist liquid was set to 0.2 cc/sec. The first coating speed and the supply period were set to the values which have been set in advance so as to bring the variation in the film thickness close to a minimum value.

Sample 2) A resist film was formed on the front surface Wa of the wafer W according to the same procedure as in steps S01 to S29 except that the cooling of the wafer W, the cooling of the resist liquid in the liquid source 32, and the supply of the cooling fluid to the outer peripheral portion of the rear surface Wb of the wafer W are not performed. The flow rate of the resist liquid was set to 0.2 cc/sec. The first coating speed was set to a value which has been set in advance so as to bring the variation in the film thickness close to a minimum value.

As a result of measuring the variation in the film thickness in Sample 1 and the variation in the film thickness in Sample 2, the variation in the film thickness in Sample 1 was about 15% of the variation in the film thickness in Sample 2. From this result, it was confirmed that the variation in the film thickness is significantly reduced by performing the cooling of the wafer W, the cooling of the resist liquid in the liquid source 32, and the supply of the cooling fluid to the outer peripheral portion of the rear surface Wb of the wafer W.

The supply of the cooling fluid may be started after the supply of the film-forming liquid is stopped. In this case, a larger amount of the film-forming liquid can be retained on the wafer W by appropriately performing the drying of the film-forming liquid in the outer peripheral portion of the liquid film before the supply of the film-forming liquid is stopped. As a result, it is possible to prevent the liquid film thickness from becoming too small.

The supply of the cooling fluid may be stopped before the rotation of the wafer W is stopped. The supply of the cooling fluid suppresses the decrease in the fluidity of the film-forming liquid on the outer peripheral portion of the wafer W, but delays the drying of the film-forming liquid. On the other hand, by stopping the supply of the cooling fluid before the rotation of the wafer W is stopped, it is possible to achieve both the uniformity of the film thickness and the drying efficiency of the film-forming liquid.

The cooling fluid may contain an organic solvent. In this case, the outer peripheral portion of the wafer W can be cooled more effectively. Accordingly, the present coating method is more effective for improving the in-plane uniformity of the film thickness.

The cooling fluid may be supplied to the outer peripheral portion of the rear surface Wb of the wafer W along an inclined line which is inclined so as to come close to the outer periphery We of the wafer W as it approaches the rear surface Wb of the wafer W. In this case, the cooling action of the cooling fluid can be further concentrated on the outer peripheral portion of the wafer W. Accordingly, the present coating method is more effective for improving the in-plane uniformity of the film thickness.

The coating method may further include exhausting the gas in the accommodation space of the wafer W from the exhaust port 74a below the rear surface Wb of the wafer W, at least when supplying the cooling fluid to the outer peripheral portion of the rear surface Wb of the wafer W. The cooling fluid may be supplied to the outer peripheral portion of the rear surface Wb of the wafer W at a flow rate smaller than the exhaust amount of the gas from the exhaust port 74a. In this case, it is possible to prevent the liquid film from being deteriorated by the cooling fluid that flows around toward the front surface Wa of the wafer W.

Supplying the film-forming liquid to the center of the front surface Wa of the wafer W may include supplying the film-forming liquid from the liquid source 32 to the nozzle 31 opened toward the center of the front surface Wa of the wafer W through the throttle portion 35 and the valve 33. The amount of the film-forming liquid discharged from the nozzle 31 (hereinafter referred to as “discharge amount”) varies depending on the variation in the supply pressure of the film-forming liquid supplied from the liquid source 32. The variation in the discharge amount affects the in-plane uniformity of the film thickness. On the other hand, by supplying the film-forming liquid through the throttle portion 35, it is possible to suppress the variation in the discharge amount depending on the variation in the supply pressure. Since the throttle portion 35 is arranged upstream of the valve 33 (near the liquid source 32), it is also possible to suppress the overshooting of the discharge amount when the valve 33 is opened or closed. Accordingly, the present coating method is more effective for improving the in-plane uniformity of the film thickness.

The coating method may further include repeating sample preparation and sample measurement while changing a combination of the first coating speed and the supply period, until a variation in film thickness on a sample substrate becomes equal to or lower than a predetermined level, wherein the sample preparation includes: rotating the sample substrate at the first coating speed while supplying the film-forming liquid to the center of the front surface of the sample substrate, stopping the supply of the film-forming liquid before the film-forming liquid supplied to the front surface of the sample substrate reaches the outer periphery of the sample substrate, continuing to rotate the sample substrate at the second coating speed after the supply of the film-forming liquid is stopped, and supplying the cooling fluid to the outer peripheral portion of the rear surface of the sample substrate during the supply period, and wherein the sample measurement includes measuring a film thickness of a film formed on the front surface of the sample substrate by the sample preparation. The in-plane uniformity of the film thickness is greatly affected by the first coating speed and the supply period. The first coating speed and the supply period can be appropriately set by repeating the sample preparation and the sample measurement until the variation in the film thickness on the sample substrate becomes equal to or less than the predetermined level. Accordingly, the present coating method is more effective for improving the in-plane uniformity of the film thickness.

Repeating the sample preparation and the sample measurement may include bringing the variation in the film thickness on the sample substrate close to a minimum value by setting the supply period to a predetermined value and changing the first coating speed, or may include reducing the variation in the film thickness on the sample substrate by setting the first coating speed to a predetermined value and changing the supply period. In this case, it is possible to more effectively set the first coating speed and the supply period.

Reducing the variation in the film thickness on the sample substrate by setting the first coating speed to a predetermined value and changing the supply period may include bringing a film thickness distribution on the sample substrate close to a quartic or higher even-order function by setting the first coating speed to a predetermined value and changing the supply period. The film thickness profile before the first coating speed is optimized tends to become a profile in which the film thickness gradually increases from the center of the wafer W to a position having a certain distance from the center of the wafer W and the film thickness gradually decreases from the position to outer periphery Wc. By bringing the profile close to a quartic or higher even-order function (particularly a quartic function), the film thickness variation after the first coating speed optimization tends to become small. Accordingly, when the sample preparation and the sample measurement are repeated while changing the supply period with the first coating speed set to a predetermined value, the first coating speed and the supply period can be set more efficiently by bringing the film thickness distribution close to a quartic or higher even-order function.

The coating method may include: preparing a plurality of sample substrates by repeating, while changing a combination of the first coating speed and the supply period, rotating the sample substrate at the first coating speed while supplying the film-forming liquid to the center of the front surface of the sample substrate, stopping the supply of the film-forming liquid before the film-forming liquid supplied to the front surface of the sample substrate reaches the outer periphery of the sample substrate, continuing to rotate the sample substrate at the second coating speed after the supply of the film-forming liquid is stopped, and supplying the cooling fluid to the outer peripheral portion of the rear surface of the sample substrate during the supply period; measuring a film thickness of a film formed on the front surface of each of the plurality of sample substrates; and setting the first coating speed and the supply period so as to reduce a variation in the film thickness of each of the plurality of sample substrates based on the variation in the film thickness of each of the plurality of sample substrates. In this case, the first coating speed and the supply period can be appropriately set based on the data indicating the relationship of the first coating speed, the supply period, and the variation in the film thickness. Accordingly, the present coating method is more effective for improving the in-plane uniformity of the film thickness.

Although the embodiments have been described above, the present disclosure is not necessarily limited to the above-described embodiments. Various modifications may be made without departing from the spirit of the present disclosure. The target substrate is not limited to the semiconductor wafer, and may be, for example, a glass substrate, a mask substrate, an FPD (Flat Panel Display), or the like. The coating method described above may also be applied to formation of films other than the resist film (e.g., the lower layer film and the upper layer film described above).

According to the present disclosure in some embodiments, it is possible to provide a coating method and a coating apparatus which are effective for improving the in-plane film thickness uniformity of a film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A coating method, comprising:
rotating a substrate at a first rotation speed while supplying a film-forming liquid to a center of a front surface of the substrate;
stopping the supply of the film-forming liquid before the film-forming liquid supplied to the front surface of the substrate reaches an outer periphery of the substrate;
continuing to rotate the substrate at a second rotation speed after the supply of the film-forming liquid is stopped; and
supplying a cooling fluid, which is a gas-liquid mixture, to an outer peripheral portion of a rear surface of the substrate during a supply period for the substrate including at least a part of a period from a time when the supply of the film-forming liquid is stopped to a time when the rotation of the substrate at the second rotation speed is completed.

2. The coating method of claim 1, wherein the supply of the cooling fluid is started after the supply of the film-forming liquid is stopped.

3. The coating method of claim 1, wherein the supply of the cooling fluid is stopped before the rotation of the substrate is stopped.

4. The coating method of claim 1, wherein the cooling fluid contains an organic solvent.

5. The coating method of claim 4, wherein the cooling fluid includes a gas and a solvent having volatility equal to or higher than volatility of IPA.

6. The coating method of claim 1, wherein the cooling fluid is supplied to the outer peripheral portion of the rear surface of the substrate along a line inclined so as to come close the outer periphery of the substrate as the line approaches the rear surface of the substrate.

7. The coating method of claim 1, further comprising:
exhausting a gas in an accommodation space of the substrate from an exhaust port below the rear surface of the substrate at least when supplying the cooling fluid to the outer peripheral portion of the rear surface of the substrate,
wherein the cooling fluid is supplied to the outer peripheral portion of the rear surface of the substrate at a flow rate smaller than an exhaust amount of the gas exhausted from the exhaust port.

8. The coating method of claim 1, wherein supplying the film-forming liquid to the center of the front surface of the substrate includes supplying the film-forming liquid from a supply source of the film-forming liquid to a nozzle opened toward the center of the front surface of the substrate through a throttle portion and a valve.

9. The coating method of claim 1, further comprising:
repeating sample preparation and sample measurement while changing a combination of the first rotation speed and a supply period for a sample substrate, until a variation in film thickness on the sample substrate becomes equal to or lower than a predetermined level,
wherein the sample preparation includes:
rotating the sample substrate at the first rotation speed while supplying the film-forming liquid to a center of a front surface of the sample substrate;
stopping the supply of the film-forming liquid to the sample substrate before the film-forming liquid supplied to the front surface of the sample substrate reaches an outer periphery of the sample substrate;
continuing to rotate the sample substrate at the second rotation speed after the supply of the film-forming liquid to the sample substrate is stopped; and
supplying the cooling fluid to an outer peripheral portion of a rear surface of the sample substrate during the supply period for the sample substrate including at least a part of a period from a time when the supply of the film-forming liquid to the sample substrate is stopped to a time when the rotation of the sample substrate is completed, and
wherein the sample measurement includes measuring a film thickness of a film formed on the front surface of the sample substrate by the sample preparation.

10. The coating method of claim 9, wherein repeating the sample preparation and the sample measurement may include reducing the variation in the film thickness on the sample substrate by changing the first rotation speed while setting the supply period for the sample substrate to a predetermined value.

11. The coating method of claim 9, wherein repeating the sample preparation and the sample measurement may include reducing the variation in the film thickness on the sample substrate by changing the supply period for the sample substrate while setting the first rotation speed to a predetermined value.

12. The coating method of claim 11, wherein reducing the variation in the film thickness on the sample substrate by changing the supply period for the sample substrate while setting the first rotation speed to the predetermined value includes bringing a film thickness distribution on the sample substrate close to a quartic or higher even-order function by changing the supply period for the sample substrate while setting the first rotation speed to the predetermined value.

13. The coating method of claim 1, further comprising:
preparing a plurality of sample substrates by repeating, while changing a combination of the first rotation speed and a supply period for each sample substrate:
rotating the sample substrate at the first rotation speed while supplying the film-forming liquid to a center of a front surface of the sample substrate;
stopping the supply of the film-forming liquid to the sample substrate before the film-forming liquid supplied to the front surface of the sample substrate reaches an outer periphery of the sample substrate;
continuing to rotate the sample substrate at the second rotation speed after the supply of the film-forming liquid to the sample substrate is stopped; and
supplying the cooling fluid to an outer peripheral portion of the rear surface of the sample substrate during the supply period for the sample substrate including at least a part of a period from a time when the supply of the film-forming liquid to the sample substrate is stopped to a time when the rotation of the sample substrate is completed;
measuring a film thickness of a film formed on the front surface of each of the plurality of sample substrates; and
setting the first rotation speed and the supply period for the sample substrate so as to reduce a variation in the film thickness of each of the plurality of sample substrates based on the variation in the film thickness of each of the plurality of sample substrates.

14. A coating apparatus, comprising:
a rotary holder configured to hold and rotate a substrate;
a liquid supplier configured to supply a film-forming liquid to a center of a front surface of the substrate held by the rotary holder;
a cooling fluid supplier configured to supply a cooling fluid, which is a gas-liquid mixture, to an outer peripheral portion of a rear surface of the substrate;
a first coating controller configured to rotate the substrate by the rotary holder at a first rotation speed while supplying the film-forming liquid to the center of the front surface of the substrate by the liquid supplier and configured to stop the supply of the film-forming liquid by the liquid supplier before the film-forming liquid supplied to the front surface of the substrate reaches an outer periphery of the substrate;
a second coating controller configured to continue rotating the substrate by the rotary holder at a second rotation speed after the supply of the film-forming liquid by the liquid supplier is stopped; and
a cooling controller configured to supply the cooling fluid to the outer peripheral portion of the rear surface of the substrate by the cooling fluid supplier during a supply period including at least a part of a period from a time when the supply of the film-forming liquid by the liquid supplier is stopped to a time when the rotation of the substrate at the second rotation speed is completed.

15. A non-transitory computer-readable storage medium that stores a program for causing a coating apparatus to execute the coating method of claim 1.
